(19) United States
(12) Patent Application Publication
(10) Pub. No.: US 2011/0304319 A1
(43) Pub. Date: Dec. 15, 2011

(54) MULTIMETER WITH FLEXIBLE CURRENT SENSOR

(75) Inventor: Po-Chao TAN, Chung-Ho City (TW)

(73) Assignee: Brymen Technology Corporation

(21) Appl. No.: 12/797,432

(22) Filed: Jun. 9, 2010

(51) Int. Cl. G01R 15/00

(52) U.S. Cl. 324/115

(57) ABSTRACT

The multimeter of the invention includes main body, a current sensor and a flexible tube. The main body is provided with a display. The current sensor is electrically connected to the main body via a wire. The flexible tube is connected between the main body and current sensor. And the wire is accommodated in the flexible tube. Therefore, the current sensor can be adjusted to any direction, angle and position.

### BACKGROUND OF THE INVENTION

1. Technical Field

The invention generally relates to electric instruments, particularly to multimeters.

2. Related Art

A multimeter is a multi-function electric instrument usually including an ammeter, a voltmeter and an ohmmeter. In a conventional multimeter with current sensor, the current sensor is integratedly disposed on the multimeter main body.

However, the current sensor on the top of the multimeter is a part of the main body and can not be bent or rotated against the main body. This multimeter may not be operated conveniently because it can not be adjusted to the best position suitable for both a user and a wire to be measured. Usually, a user must finish the measurement first, and then reads the shown value.

### SUMMARY OF THE INVENTION

An object of the invention is to provide a multimeter which has a flexibly extended current sensor capable of changing directions, angles and positions. A user can bend and/or rotate the flexible current sensor to fit both the wire to be measured and him/herself.

To accomplish the above object, the multimeter of the invention includes main body, a current sensor and a flexible tube. The main body is provided with a display. The current sensor is electrically connected to the main body via a wire. The flexible tube is connected between the main body and current sensor. And the wire is accommodated in the flexible tube. Therefore, the current sensor can be adjusted to any direction, angle and position.

### BRIEF DESCRIPTION OF THE DRAWINGS

FIG. 1 shows the first embodiment of the invention;

FIG. 2 shows the second embodiment of the invention; and

FIG. 3 is a partially enlarged cross section view of FIG. 2.

### DETAILED DESCRIPTION OF THE INVENTION

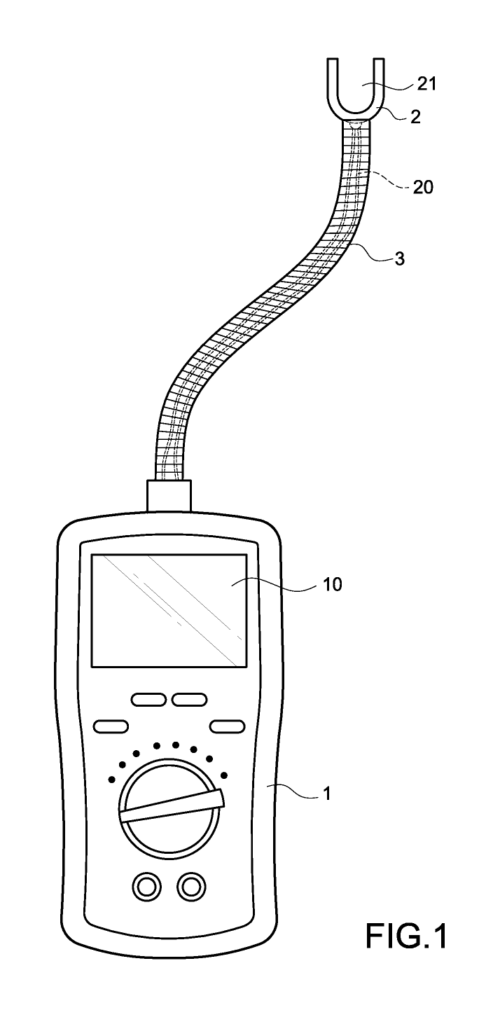

Please refer to FIG. 1, which shows the first embodiment of the invention. The multimeter with flexible current sensor according to the invention includes a main body 1, a current sensor 2 and a flexible tube connected therebetween.

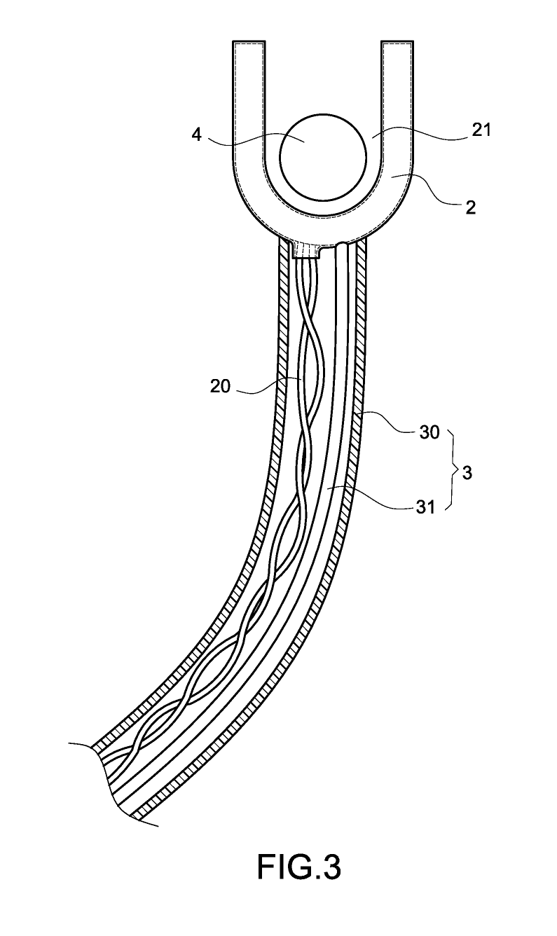

The main body 1 has inherent functions of an ordinary multimeter. There is a display 10 on the main body 1. The current sensor 2 for measuring current may be of a U shape or a clamp and electrically connects to the main body 1 through a wire 20 for sending signals to the main body 1. The current sensor 2 has a recess portion 21 for being penetrated by a current-carrying wire 4 (as shown in FIG. 3) and detects the current by the induced magnetic field.

The flexible tube 3, which is made of soft plastic, connects between the main body 1 and the current sensor 2. The wire 20 is accommodated in the flexible tube 3. In the first embodiment of the invention, the flexible tube 3 is a gooseneck which can be bent and wrenched. A user may hold the main body 1 in one hand and at a suitable position and the flexible tube 3 can be bent or wrenched to reach the current-carrying wire 4 to be measured. The user may perform the measurement one-handedly. And it is so convenient to read the shown data on the display 10 without environmental restriction.

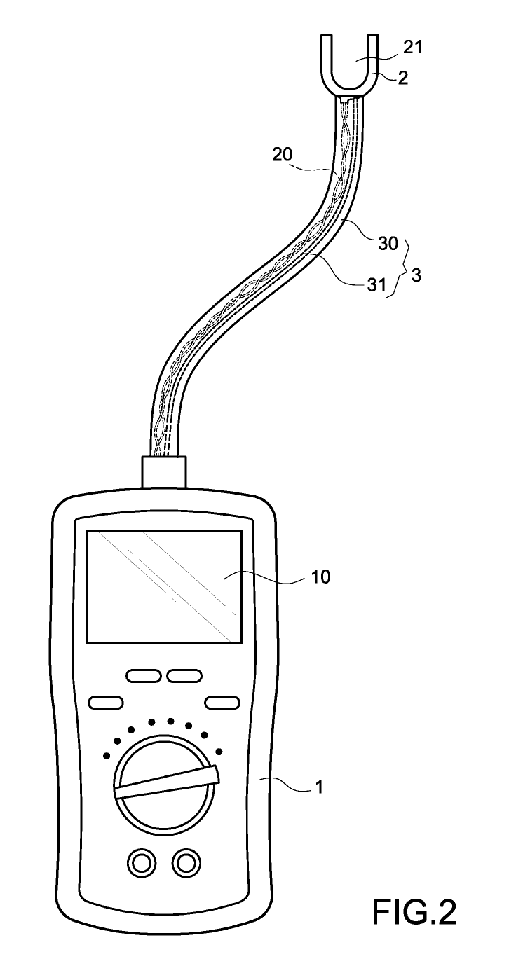

FIG. 2 shows the second embodiment of the invention. In this embodiment, the flexible tube 3 is composed of a soft sleeve 30 and a flexible supporting rod 31 connecting between the main body 1 and current sensor 2. The wire 20 and supporting rod 31 are accommodated in the soft sleeve 30.

Embodiments of the invention have been described. Nevertheless, it will be understood that various modifications may be made without departing from the spirit and scope of the invention. Accordingly, other embodiments are the scope of the following claims.

What is claimed is:

1. A multimeter comprising:
a main body having a display;
a current sensor electrically connecting to the main body through a wire; and
a flexible tube, mechanically connecting between the main body and the current sensor, and accommodating the wire therein.

2. The multimeter of claim 1, wherein the current sensor is of a U shape.

3. The multimeter of claim 1, wherein the current sensor is a clamp.

4. The multimeter of claim 1, wherein the flexible tube is a gooseneck.

5. The multimeter of claim 1, wherein the flexible tube is made of soft plastic.

6. The multimeter of claim 1, wherein the flexible tube is composed of a soft sleeve and a flexible supporting rod, and the wire and supporting rod are accommodated in the soft sleeve.
